(19) United States
(12) Patent Application Publication
(10) Pub. No.: US 2017/0179275 A1
(43) Pub. Date: Jun. 22, 2017

(54) FIN-TYPE SEMICONDUCTOR STRUCTURE AND METHOD FOR FORMING THE SAME

(71) Applicant: Tang Zong, Hunan (CN)

(72) Inventor: Di Li, Hunan (CN)

(21) Appl. No.: 15/301,464

(22) PCT Filed: Apr. 1, 2015
(86) PCT No.: PCT/CN2015/075721

§ 371 Date: Oct. 3, 2016

(30) Foreign Application Priority Data
Apr. 4, 2014 (CN) 201410135438.0
Apr. 4, 2014 (CN) 201410135439.5
Apr. 4, 2014 (CN) 201410135448.4
Apr. 4, 2014 (CN) 201420163556.8

(51) Int. Cl. H01L 29/78; H01L 21/306; H01L 29/66; H01L 29/417; H01L 29/06

(52) U.S. Cl. CPC H01L 29/785; H01L 29/41791; H01L 29/0653; H01L 29/66795; H01L 21/30604; H01L 21/30625; H01L 29/66545; H01L 2029/7858

(57) ABSTRACT

The present disclosure relates to a fin-type semiconductor structure which can effectively control a leakage current between a source region and a drain region and improve controllability of a gate electrode. The fin-type semiconductor structure includes a fin-type substrate provided with a lower substrate and a fin part, a source region and a drain region formed in the fin part, a gate structure formed across the fin part between the source region and the drain region, a shallow trench isolation formed at both sides of the fin part and below the gate structure, and an isolation region formed in the fin part. The isolation region can be substantially located below the source region, and/or substantially located below the drain region, and/or substantially located below the gate structure. The present disclosure also relates to a method for forming the above semiconductor structure.

### BACKGROUND OF THE DISCLOSURE

Field of the Disclosure

The present disclosure relates to the field of semiconductor design and manufacturing technology, and more particularly, to a fin-type semiconductor structure and the method for forming the same.

Description of the Related Art

Fin-type field effect transistor, which is called FinFET, is a novel complementary metal oxide semiconductor (CMOS) transistor. FinFET is such named because it has a shape similar to a fin of a fish, and it is also named as tri-gate MOSFET.

FinFET is a novel design compared with a conventional standard field effect transistor. For a conventional transistor structure, a gate is provided for controlling current to pass or not, which controls on and off state of the device at only one side of the gate. The conventional gate has a planar structure. For a FinFET structure, the gate has a three dimensional branch structure like a fin, which controls on and off states of the device at both sides of the gate. Compared with the conventional transistor, the novel design can improve controllability of the device and greatly reduce a gate length.

However, the conventional FinFET still has problem that a leakage current between a source region and a drain region may pass through the substrate due to characteristics of its substrate structure. It sometimes generates a large leakage current because the gate length is small. Moreover, another problem is that capacitance between a source region and a drain region is relatively high.

Accordingly, it is desirable to provide a FinFET which decreases a leakage current between the source region and drain region and further improving controllability of the gate electrode.

### SUMMARY OF THE DISCLOSURE

The disclosure provides a fin-type semiconductor structure and method for forming the same, for solving at least one of the above technical problems. The fin-type semiconductor structure according to the disclosure can further decrease a leakage current between a source region and a drain region and improve controllability of the gate electrode. Thus, the semiconductor device has improved performance and increased life.

The fin-type semiconductor structure comprises: a fin-type substrate provided with a lower substrate and a fin part; a source region and a drain region formed in the fin part; a gate structure formed across the fin part between the source region and the drain region, with a portion of the fin part below the gate structure being a channel region; a shallow trench isolation formed at both sides of the fin part; and one or more isolation regions formed in the fin part between the channel region and the lower substrate.

The fin part may have rectangular cross sections at both ends, or triangular cross sections at both ends, a top surface of the fin part may be a smooth and curved surface.

The fin-type semiconductor structure may comprise an interlayer dielectric at both sides of the gate structure, and the interlayer dielectrics have the same height as that of the gate structure.

The isolation region may be located below the source region and/or the drain region, or located below the gate structure, having a length equal to or smaller than that of the gate structure.

The fin-type semiconductor structure may comprise a sacrificial region formed in the fin part, and the isolation region is formed in the sacrificial region which is exposed at both sides of the fin part. The sacrificial region may be a sacrificial layer penetrating through the fin part, or one or more sacrificial segments.

The fin part may be provided with an upper fin part, a sacrificial layer and a lower fin part. The upper fin part may be made of Si, and a SiGe epitaxial layer may be formed on a surface of the fin part. Or, the upper fin part may be made of SiGe, and a Si epitaxial layer is formed on the surface of the fin part. A Si epitaxial layer may be further formed on the SiGe epitaxial layer.

An under-cut region may be formed at both sides of the isolation region, which is recessed with a distance with respect to both sides of the fin part less than one quarter of a width of the fin part.

According to another aspect of the present disclosure, there is also provided a method for manufacturing a semiconductor device, comprising:

step A, the substrate is provided to form a fin-type substrate having a lower substrate and a fin part having a sacrificial region;

step B, etching a portion of or all of the sacrificial region to form a cavity, forming an isolation region by filling the cavity with an insulating material,

forming a shallow trench isolation continuously by the insulating material,

exposing a top surface of the fin part by chemical mechanical planarization, and etching the shallow trench isolation to expose the fin part;

step C, forming a dummy gate structure across the fin part, forming sidewalls at both sides of the dummy gate structure, and forming a source region and a drain region in the fin part at both sides of the dummy gate structure;

step D, forming a metal gate structure by a replacement gate process in which the dummy gate structure is replaced.

Step A may comprise a step of providing a substrate having a sacrificial region which penetrates through the entire substrate;

or providing the substrate and forming a sacrificial region having one or more sacrificial segments by ion implantation;

forming an etching protection layer on the substrate, forming a mask on the etching protection layer, etching the etching protection layer to expose a portion of the substrate, etching a portion of the substrate to form a fin part having an upper fin part, a sacrificial layer and a lower fin part.

The step A may comprise: forming the fin part by etching, the fin part having rectangular cross sections or triangular cross sections at both ends.

The method may comprise etching the fin part below the drain region and/or source region to form a cavity; or etching a portion of or all of the sacrificial region below the gate structure to form a cavity.

After step B, the method may comprise a step of forming a SiGe epitaxial layer on the surface of the fin part and the cavity by epitaxial growth, or forming a Si epitaxial layer on the surface of the fin part and the cavity by epitaxial growth. The method may further comprise a step of forming a Si epitaxial layer on the SiGe epitaxial layer by epitaxial growth.

The isolation region is etched back to form an under-cut region before forming the dummy gate structure at step C. The dummy gate structure formed at step C covers the surface of the under-cut region and extends into the fin part.

### BRIEF DESCRIPTION OF THE DRAWINGS

The above and/or additional aspects and advantages according to the disclosure will become more apparent and understandable from the following description which is taken in connection with the accompanying drawings, wherein,

FIGS. 1 to 11 are schematic diagrams of various stages of a method for forming a fin-type semiconductor device according to an embodiment of the present disclosure;

FIG. 11 is a structural diagram of an example semiconductor device according to an embodiment of the present disclosure;

FIG. 12 is a structural diagram of an example fin-type substrate according to an embodiment of the present disclosure;

FIG. 13 is a structural diagram of an example structure in which another cavity is formed according to an embodiment of the present disclosure;

FIG. 14 is a structural diagram of an example under-cut region according to an embodiment of the present disclosure;

FIG. 15 is a structural diagram of a SiGe layer and Si layer formed on the surface of the fin part and the cavity according to an embodiment of the present disclosure;

FIG. 16 is a structural diagram of an example semiconductor device in which a sidewall has been formed according to a third embodiment of the present disclosure;

FIG. 17 is a structural diagram of an example semiconductor device in which an interlayer dielectric has been formed according to a third embodiment of the present disclosure;

FIG. 18 is a structural diagram of an example semiconductor device in which a dummy gate structure has been removed according to a third embodiment of the present disclosure;

FIG. 19 is a structural diagram of an example semiconductor device in which an isolation region and a gate structure have been formed according to a third embodiment of the present disclosure.

### DETAILED DESCRIPTION OF THE DISCLOSURE

The present disclosure will be described below with those preferred embodiments in connection with attached drawings. The same reference numerals are used throughout the Figures to indicate the same or similar part or the part having the same or similar functions. The embodiments described below in connection with the attached drawings are only illustrative for explaining the present disclosure, but are not construed as limiting the invention.

The disclosure below provides various embodiments or examples for carrying out the different structures of the present disclosure. For the simplicity of the disclosure, the following description illustrates the members and configuration of the specific embodiments. The objective is not to limit the present disclosure, only for examples. Moreover, reference numerals and/or letters are repeatedly used in various embodiments. The repetition is for simplicity and clarity, but does not represent relationship between various embodiments and/or settings to be discussed below. Moreover, the disclosure provides various specific processes and materials. Nevertheless, one skilled person in the art will appreciate that other processes and/or materials can also be used in the embodiments.

Directions in the device according to the embodiments of the present disclosure are defined before the description of the embodiments. A z-direction is the one along which a fin part protrudes from the substrate, a x-direction is the one which is perpendicular to the z-direction and parallel to the top of the fin part, a y-direction is the one which is perpendicular to both the z-direction and the x-direction.

### The First Embodiment

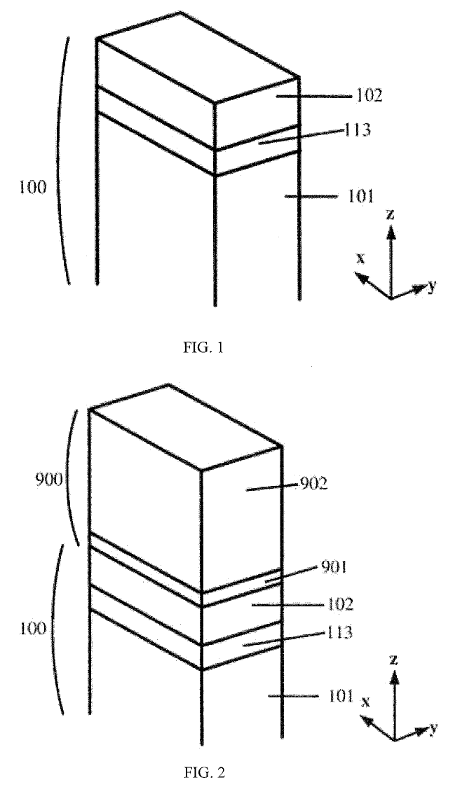

The present disclosure provides a semiconductor structure and a method for manufacturing the same. FIGS. 1 to 11 are schematic diagrams of various stages of the method. The steps of the method according to an embodiment of the present disclosure will be described in detail hereinafter in connection with the appended drawings.

At step A, the substrate 100 is provided, which has a lower substrate 180 and a fin part 110, and the sacrificial region 113 is formed in the fin part 110, as shown in FIG. 6.

As shown in FIG. 1, a substrate 100 is provided for the preparation process of the substrate. The substrate 100 includes a first substrate 101 of silicon, and then a layer of the sacrificial region 113 is formed on the first substrate 101 by epitaxial growth. In the embodiment, the sacrificial region 113 is a sacrificial layer penetrating through the entire substrate. The sacrificial region 113 is preferably made of SiGe, n-type doped silicon, or the like. Its thickness is preferably between 5 to 50 nm. A second substrate 102 is formed continuously on the sacrificial layer 113 by epitaxial growth. The second substrate 102 becomes the basis of the upper fin part 114 in the fin-type part 110 which will be formed in the following steps. Thus, the substrate 100 is formed to have the sacrificial region 113. Specifically, the sacrificial layer 113 may be made of SiGe with 40% Ge content, the second substrate 102 may be made of Si or SiGe with a Ge content lower than that of the sacrificial layer. More preferably, the second substrate 102 may be made of SiGe with a Ge content 10% lower than that of the sacrificial layer. The second substrate 102 may be made of different materials in accordance with the different performance requirements of the devices to be formed. For example, the second substrate 102 is preferably made of silicon for NMOS. However, the second substrate 102 is preferably made of silicon germanium with 30% Ge content for PMOS. The structure in which the second substrate is made of SiGe can improve mobility of carrier holes in PMOS devices, the performance of the channel region and the controllability of the gate electrode.

After forming the substrate 100 having the sacrificial layer, a fin part is to be formed. As shown in FIG. 2, an etching protection layer 900 is formed on the surface of the substrate 100. There may be various choices for forming etching protection layer 900. Specifically, an oxide layer 901 is deposited with a thickness for example, between 10 and 200 nm, and a nitride layer 902 is formed on the oxide layer 901 with a thickness, for example, between 10 and 200 nm. Thus, the etching protection layer 900 is formed. As shown in FIG. 3, a mask with a predetermined width in the y-direction is formed on the etching blocking layer 900 for protecting a portion of the etching protection layer 900. The predetermined width is determined by the width of the top surface of the fin part in the y-direction, for example, which is preferably in a range between 1 and 10 nm. Then, by selectively etching the nitride layer 902 and the oxide layer 901 of the etching protection layer 900, the structure as shown in FIG. 4 is formed to expose a portion of the top surface of the substrate 100.

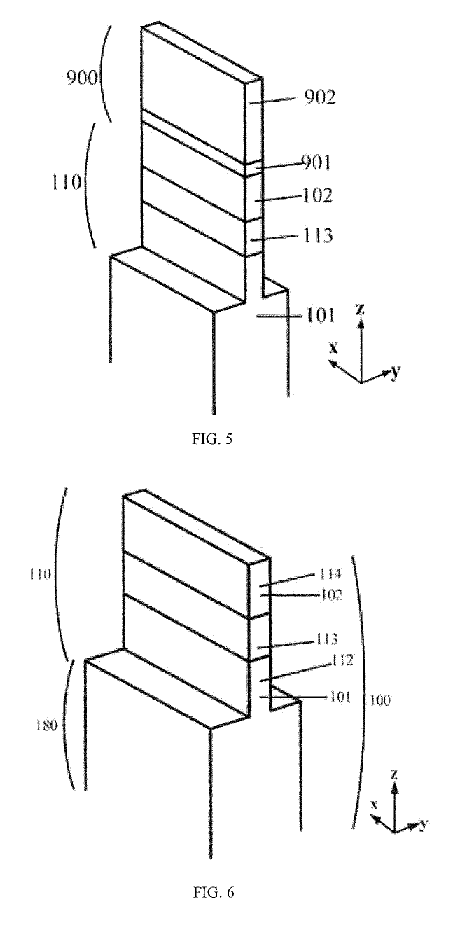

Then, the substrate 100 is etched with the etching protection layer 900 as a mask to form the fin part 110, as shown in FIG. 5. The fin part 110 is provided with an upper fin part 114, a sacrificial layer 113 penetrating through the fin part and a lower fin part 112, as shown in FIG. 6. The upper fin part 114 is formed on the second substrate 102, and the lower fin part 112 is formed on a portion of the first substrate 101. The lower substrate 180 and fin part 110 constitute the fin-type substrate 100. The shape of fin part 110 may be determined in view of actual requirements, and may be controlled by the etching process and parameters. For example, the fin part 110 with rectangular cross sections at both ends is formed, as shown in FIG. 6, the fin part 210 with triangular cross sections at both ends is formed, as shown in FIG. 12.

In view of the fact whether the first substrate 101 and the second substrate 102 are made of the same material or not, the upper fin part 114 and the lower fin part 112 may be both made of Si, or the upper fin part 114 may be preferably made of SiGe with 30% Ge content, while the lower fin part 112 may be made of Si. In view of actual requirements for the device performance, the upper fin part 114 and the lower fin part 112 may be made of other materials. Those skilled in the art can select and change these materials in view of actual requirements, all of which are in the scope of the present disclosure

Selectively, the top surface 111 of the fin part can be rounded so that the top surface 111 of the fin part has a smooth and curved surface, as shown in FIG. 7. The function is to reduce the local electric field strength of the device and enhance the reliability of the device. The smoothing can be implemented by various methods, such as isotropic etching, annealing process in hydrogen environment and with a temperature greater than 700 degrees centigrade and so on.

Then, step B is followed. At step B, a cavity 200 is formed by etching a portion of the sacrificial layer 113, and the cavity 200 is filled with an insulating material to form the isolation region 300 and the shallow trench isolation 105.

Firstly, the surface of the fin part 110 is uniformly coated with photoresist. A portion of the sacrificial layer 113 and the fin part 110, which will be remained, is blocked by a mask. The other portion of the sacrificial layer 113, which will be removed to form the cavity 200, is exposed. A portion of the photoresist is not covered by the mask and exposed. Then, the exposed portion of the photoresist is removed by washing, and the sacrificial layer 113 is etched. The cavity 200 penetrating in the y-direction is formed between the upper fin part 114 and the lower fin part 112, as shown in FIG. 7. The cavity 200 may have a height between 5 to 50 nm in the z-direction. The sacrificial layer 113 is made of silicon germanium. If the cavity 200 is too tall, that is, the sacrificial layer 113 is too thick, defects such as dislocations are generated in the sacrificial layer 113, and possibly extend and enter into the upper trench region. The device performance may be decreased. Thus, the height of the cavity 200 is preferably between 5 and 20 nm.

Etching the cavity 200 may be implemented by a plurality of etching processes, such as dry etching, including plasma etching, wet etching and a combination of the dry etching and the wet etching. The dry etching can better control the shape and the size of the cavity so as to form a smaller cavity 200. Particularly, the last etching process of etching cavity 200 may be wet etching in order to reduce surface damage and defects due to etching.

The photoresist on the surface of the fin part 110 is removed after the etching of the cavity 200 is completed.

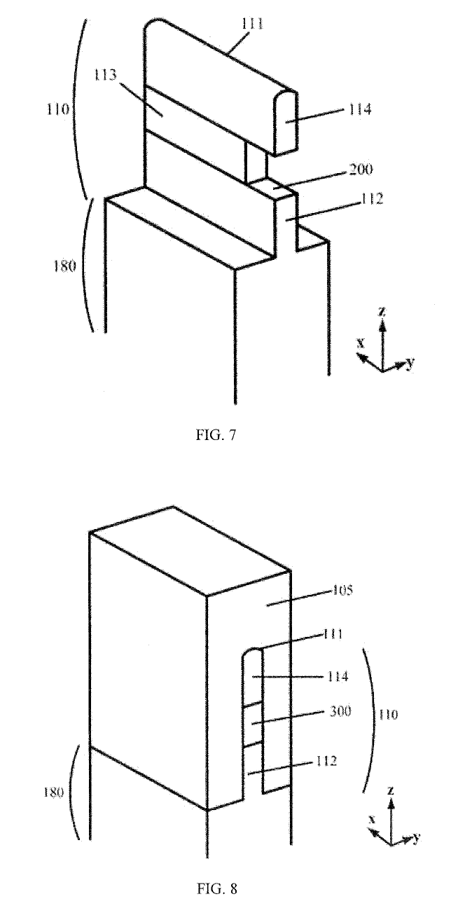

As another example of forming the cavity 200 by etching, one or more cavities 200 with different lengths may be formed at different positions in the x-direction. As shown in FIG. 13, the first cavity 2001 and the second cavity 2002 are formed. The number, location, and size of the cavities 200 may be selected in accordance with the different performance requirements for the device. When the cavity 200 is located only in the fin part below the source region 6002 or the drain region 6001, the device has better isolation effect. One side of the device without the cavity 200 has higher thermal conductivity and mechanical strength because the upper fin part 114 and the lower fin part 112 are connected tightly through the sacrificial region 113. The sacrificial layer 113, such as SiGe sacrificial layer, has better thermal conductivity than that of the isolation region 300 formed by filling the cavity with an insulating material, such as silicon oxide. The device has higher mechanical strength than that of a structure in which a cavity 200 is formed and then filled with the isolation region 300. That is because the sacrificial layer 113 and the upper fin part 114 and the lower fin part 112 are formed integrally, and are bonded tightly with each other. For example, a cavity 200 having a smaller length in the x-direction may be formed in order to provide a device with higher mechanical strength and better thermal conductivity. A plurality of cavities 200 may be formed in the sacrificial layer when it is desirable to provide a device having better isolation effect. In order to maintain mechanical strength of the device, it is necessary to keep a portion of the sacrificial layer 113. For a device having a large gate length, for example, the length of dummy gate structure in the x-direction is greater than 120 nm. However, the mechanical performance of the device will decrease if the cavity 200 has a large width in the x-direction. One or more short cavities 200 having a smaller width in the x-direction can be formed for reducing the leakage current between the source and the drain regions while maintaining good mechanical performance and strength. The length of the short cavities 200 in the x-direction should be less than four times the width of the fin part 110 in the y-direction.

Different locations of the cavity in the device will have different effects on the device performance, including the following effects.

1. The cavity 200 is formed by etching in the fin part below the drain region 6001. In this structure, the fin part below the source region 6002 and the dummy gate structure still have the sacrificial region 113 which connects the upper fin part 114 with the lower fin part 112. The structure has better thermal conductivity and higher mechanical strength. Meanwhile, the leakage current of the drain region 6001 is reduced because the drain region 6001 is isolated from the substrate.

2. The cavity 200 is formed by etching in the fin part below the drain region 6001 and a portion of the dummy gate structure. This structure can reduce the parasitic capacitance between the gate electrode and the underlying substrate, while reducing the leakage current of the drain region 6001.

3. The cavity 200 is formed by etching the sacrificial region below the dummy gate structure. The length of the cavity in the x-direction may be equal to the length of the dummy gate structure. When the length of the gate structure in the x-direction is larger, the length of the cavity in the x-direction is smaller than the length of the gate structure. This structure has an excellent short-channel effect and can effectively reduce the leakage current between the source region 6002 and the drain region 6001 below the dummy gate structure.

4. For the device with a larger gate length in the x-direction, it is preferred to form one or more short cavities 200 that are relatively short in the x-direction. This structure can improve the isolation effect, while ensuring the mechanical stability of the device and improving the yield.

After etching the cavity 200, optionally, the edges of the cavity 200 and the edges of the top surface 111 of the fin-type part are rounded. The rounding can be implemented by various methods, such as isotropic etching, annealing process under hydrogen atmosphere and with a temperature more than 700 degrees centigrade, etc. This step causes the top 111 of the upper fin part 114 to have a smooth surface, as shown in FIG. 7. The bottom surface of the upper fin part 114 can also be treated to have a smooth carved surface. The smoothing is to reduce the local electric field strength of the device and enhance the reliability of the device.

Particularly, when the cross sections of both ends of the fin part 110 are substantially rectangular, the upper fin part 114 may have a substantially rectangular parallelepiped structure with rounded corners, or of a cylindrical shape, by smoothing the edges of the cavity 200. The upper fin part 114 is formed to have a substantially rectangular shape with rounded corner if the rounding degree is low, however, if the rounding degree is high, the upper fin part 114 is formed to have a basically cylindrical structure.

The cavity 200 is filled with an insulating material to form the isolation region 300. The insulating material may be SiO2, HfO2, or the like. After the cavity 200 is filled up, the insulating material should continue to be filled to form the shallow trench isolation (STI) 105, as shown in FIG. 8. The top surface of the shallow trench isolation 105 is higher than the top 111 of the fin part. Thereafter, chemical mechanical planarization is performed to expose the top surface of the fin part. The shallow trench isolation is etched to expose the fin part 110 and the etching stops at the top surface of the isolation region 300. The isolation region 300 is partially exposed, as shown in FIG. 9.

Particularly, the fin part 110 may be thermally oxidized before filling with the insulating materials. SiO2 is formed on the surface of the fin part due to the thermal oxidation, thereby narrowing or even closing the cavity 200. After thermal oxidation, the remaining portion of the cavity and the fin part 110 should be filled with an insulating material to form a complete isolation region 300 and a shallow trench isolation 105. Thermal oxidation ensures that the lower surface of the upper fin part has good surface quality so that the mobility of the carriers in the fin part is not influenced.

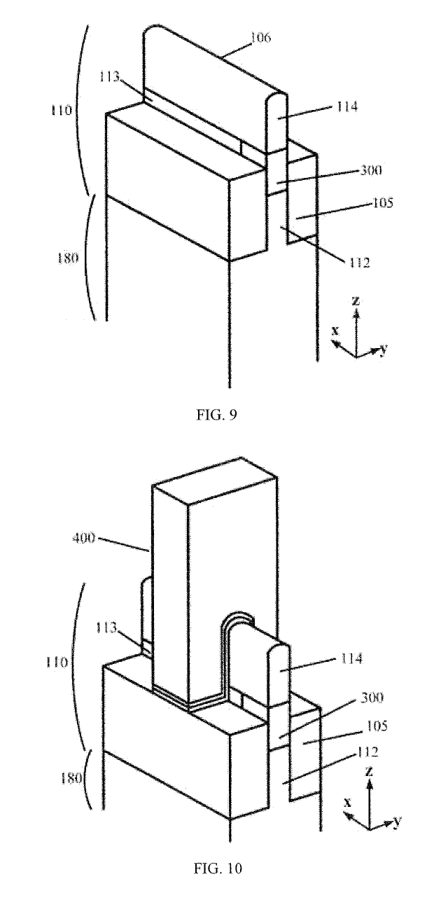

After forming the complete isolation region 300 and the shallow trench isolation 105, the isolation region 300 is exposed in the y-direction at both sides of the fin part 110, as shown in FIG. 9. Thereafter, the isolation region 300 may be etched back. When the isolation region is made of silicon dioxide, wet etching is performed with hydrofluoric acid to etch a portion of the isolation region 300. In the isolation region, an under-cut region 301 is formed on both sides in the y-direction as shown in FIG. 14. The under-cut region 301 is recessed in the y-direction with respect to both sides of the fin part by a distance less than one quarter of the width of the fin part 110 in the y-direction so as to maintain the mechanical stability of the fin-type part. When the isolation region 300 is located below the gate structure, the gate structure may cover the surface of the under-cut region 301 and extend into the fin part in the y-direction, covering a portion of the surface of the lower end of the upper fin part 114, if there is an under-cut region. This structure can enhance the gate controllability, reduce the short-channel effect, effectively enhance the gate control strength, and greatly improve the device performance

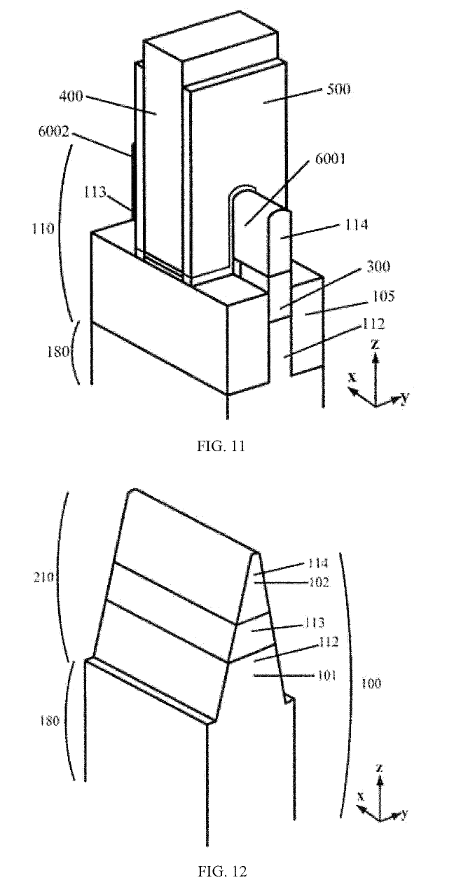

Optionally, the SiGe layer and the Si layer may be formed on the fin part 110 by epitaxial growth after etching the sacrificial layer to from the cavity 200 for the purpose of optimizing the device performance. For example, when the material of the upper fin part 114 is Si, a SiGe epitaxial layer may be formed on the surface of the fin part 110 and the cavity 200 by epitaxial growth, and a Si epitaxial layer may be further formed on the SiGe epitaxial layer by epitaxial growth, as shown in FIG. 15. When the material of the upper fin part 114 is SiGe, a Si epitaxial layer(not shown) may be formed on the surface of the fin part 110 and the cavity 200 by epitaxial growth. If the thickness of the above Si epitaxial layer is less than 5 nm, it is more suitable for forming a PMOS semiconductor device. The Si epitaxial layer having a smaller thickness can provide compressive stress on the lower SiGe epitaxial layer or the SiGe upper fin part, so as to improve the hole mobility of SiGe and improve the channel performance of the PMOS devices. If the Si epitaxial layer has a large thickness, it is more suitable to manufacture an NMOS device, because the Si epitaxial layer has better surface state, in which electrons are NMOS device carriers. For a preferred CMOS embodiment, the fin part is preferably made of silicon which has better etching selectivity comparing with the one having a SiGe sacrificial layer. The SiGe and Si epitaxial growth can be performed successively at a selected region of the fin part of the PMOS device after the cavity is formed. These preferred embodiments can be selected and varied by one skilled in the art without departing from the scope of the present disclosure.

Additionally, at step B, the shallow trench isolation (STI) 105 may be formed by filling an insulating material, and then chemical mechanical planarization is performed to expose the top surface of the fin part. The shallow trench isolation is etched to expose the fin part 110 and then the etching stops where a portion of the sacrificial region 200 is exposed. Thereafter, the etching and filling are performed at the exposed portion of the sacrificial region 200 for forming the isolation region 300.

Then, the step C is followed. At step C, a dummy gate structure is formed across the fin part 110. The fin part below the dummy gate structure is a channel region 106. A source region and a drain region are formed in the y-direction on the fin part 110 at both ends of the dummy gate.

In this embodiment, other high-k dielectric materials such as hafnium oxide, nitride and the like may be deposited on the fin part 110 and a dummy gate may be formed above the shallow trench isolation 105 and across the fin part. The additional high-k dielectric material is etched to form a dummy gate structure 400, as shown in FIG. 10.

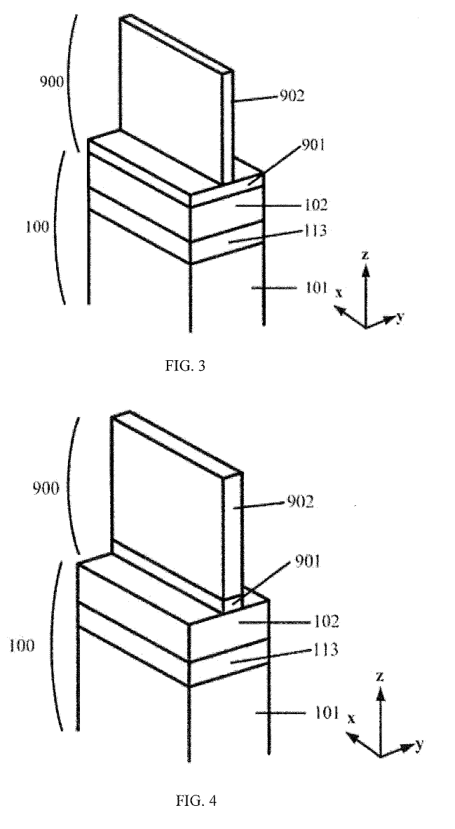

Then, a sidewall 500 is formed. A nitride material is deposited on the fin part 110 and the dummy gate structure 400 to form a nitride layer. The nitride layer on the fin part 110 and the top of the dummy gate structure 400 is etched so that the sidewall 500 is formed along the x-direction on both sides of the dummy gate structure 400 and on the fin part 110, as shown in FIG. 11.

Finally, ion implantation is performed along the x-direction in the fin part on both sides of the dummy gate structure 400, thereby forming the source region 6002 and the drain region 6001, as shown in FIG. 11. Further, before forming the source region and the drain region, ion implantation may be performed to form source/drain extension regions.

At step D, the gate structure is formed in a replacement gate process to replace the dummy gate structure.

Particularly, in order to facilitate mass production in a factory, the substrate 100 will generally have a relatively large length in the x-direction, i.e. a long substrate. Preferably, the characteristics of a single device may be previously designed, including structure features, the length in the x-direction, number, position and size of the isolation regions 300. Firstly, the steps A and B are performed in the substrate 100 having a larger length. Then, the structure in which the isolation region 300 and the shallow trench isolation 105 have already been formed is separated into individual devices in the x-direction according to the designed device length. Thereafter, steps C and D are performed. The step of the separation is independent of the steps of forming the cavity and the isolation region.

Additionally, in view of actual products, the performance requirements of various semiconductor devices themselves are not the same. Some devices do not need to form the isolation region in the fin part, such as ESD devices. If an isolation region exists in the fin part, the performance of the device will be deteriorated. Therefore, not all devices need to form an isolation region. However, the sacrificial regions are included in each substrate for the convenience of feeding and manufacture at a mass production line. In the manufacture process, in view of the device type to be formed, an isolation region can be included in the device or not. That is, a semiconductor device structure manufactured by the method according to the present disclosure may have only sacrificial regions, but no isolation regions. The sacrificial regions in the fin part are all kept to form a fin-type semiconductor structure without an isolation region.

### The Second Embodiment

Only differences between the second embodiment and the first embodiment are described hereinafter. Other aspects not being described below should be assumed to follow the same step, method or process as that of the first embodiment, and will not repeated herein.

At step A, the substrate 100 having a sacrificial region 113 is provided to form a fin-type substrate 100 having a lower substrate 180 and a fin part 110, and the sacrificial region 113 is formed in the fin part 110.

The sacrificial region 113 is not a sacrificial layer penetrating through the fin part. Instead, It appears to be one or more sacrificial segments 113, which is different from that in the first embodiment.

The sacrificial segments 113 may be formed in a process for preparing the substrate 100. In the embodiment, the substrate 100 is provided, with a mask covering a portion of the surface of the substrate 100 and exposing other portions of the substrate 100 where the sacrificial segments 113 are to be formed. Then, ion implantation is performed with preferably an n-type dopant such as P or As to form a region with a certain concentration in the substrate 100. That is, the sacrificial region 113 is formed. The substrate is etched to form a fin part 110. The sacrificial region is one or more sacrificial segments 113 located at one or more regions of the substrate. The sacrificial region is located at one or more regions of the substrate.

At step B, a cavity is formed by etching a portion of or all of the sacrificial region, and the cavity is filled with an insulating material to form the isolation region and shallow trench isolation.

A portion of or all of the sacrificial segments 113 are etched in accordance with the performance requirement of the device. The edges of the cavity 200 to be formed may be rounded, the SiGe epitaxial layer and/or Si epitaxial layer may also be formed by epitaxial growth on the surface of the fin part 110 and the cavity 200. The cavity 200 is filled with silicon dioxide or other insulating materials to form an isolation region 300 and a shallow trench isolation 105.

At step C, a dummy gate structure 400 is formed across the fin part above the shallow trench isolation 105. The fin part below the dummy gate structure is a channel region 106, a source region 6002 and a drain region 6001 are formed in the fin part on both sides of the dummy gate structure 400.

At step D, the gate structure is formed in a replacement gate process to replace the dummy gate structure.

### The Third Embodiment

Both in the first and second embodiments, the step of etching a portion of sacrificial region 113 to form the cavity 200 follows the step of providing the substrate 100. That is, step B is an etching step. The present disclosure also provides a manufacture method, in which the sacrificial region 113 may be etched after the dummy gate structure is removed. Specifically, following step A, the steps as described below are performed.

At step B, the fin part 110 is filled with an insulating material to form a shallow trench isolation (STI) 105. The insulating material may be SiO2, HfO2, or the like. The top surface of the shallow trench isolation 105 is higher than the top 111 of the fin part. Thereafter, chemical mechanical planarization is performed to expose the top surface of the fin part. Then, the shallow trench isolation is etched to expose the fin part 110 and a portion of the sacrificial region 200.

At step C, a dummy gate structure across the fin part 110 is formed. The fin part below the dummy gate structure is a channel region. A source region and a drain region are formed in the fin part 110 in the y-direction at both ends of the dummy gate 400.

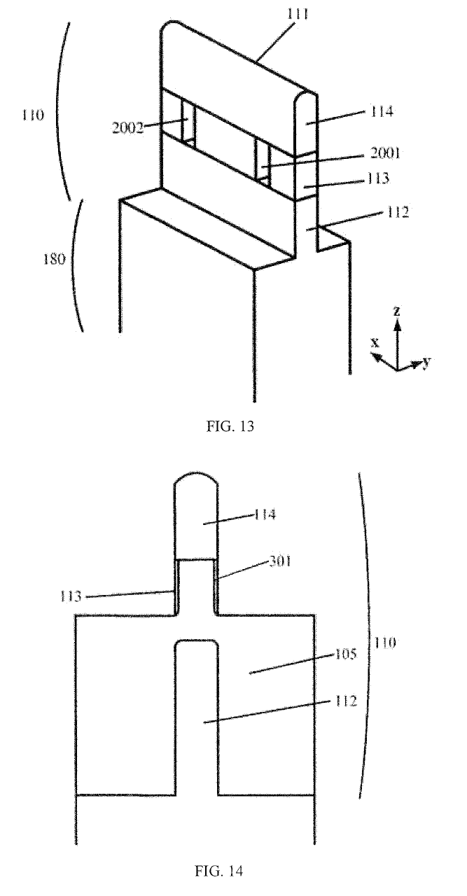

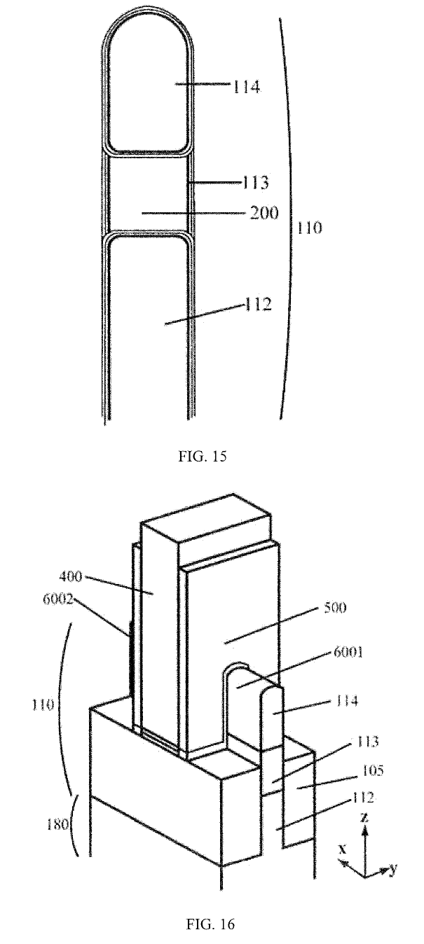

The sidewall 500 is formed in the x-direction on both sides of the dummy gate structure 400 and above the fin part 110, as shown in FIG. 16. An interlayer dielectric layer 600 is formed on both sides of the sidewall 500 in the x-direction. The interlayer dielectric layer 600 completely covers the region of the fin part 110 that are not covered by the dummy gate structure 400 and the sidewall 500. The interlayer dielectric layer 600 may has a height the same as that of the dummy gate structure 400, as shown in FIG. 17. The material of the interlayer dielectric layer may be SiO2.

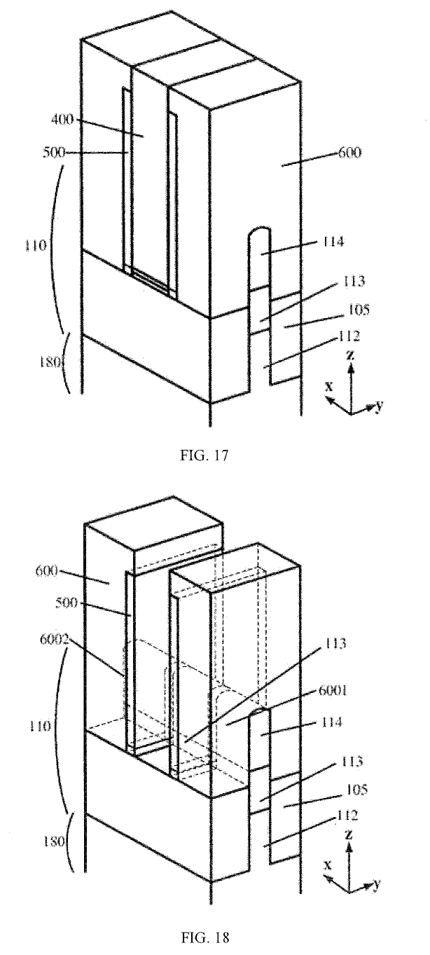

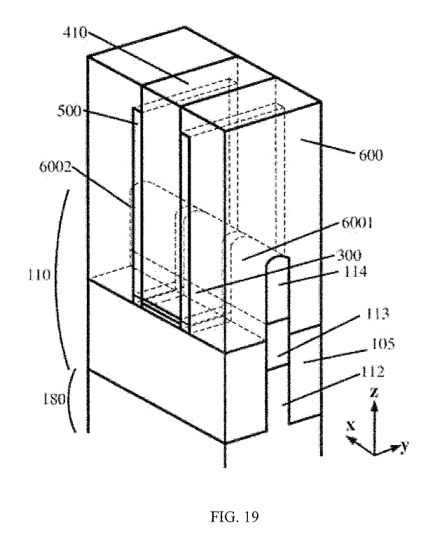

Thereafter, step D is followed. As shown in FIG. 18, firstly, the dummy gate structure 400 is etched selectively. When the dummy gate structure is entirely etched away, the fin part 110 and the sacrificial region 113 in the sidewall 500 are exposed, which are previously covered by the dummy structure. After that, a portion of the shallow trench isolation 105 between the two sidewalls 500 is etched for etching away a small portion of the shallow trench isolation 105 in the z-direction to expose the sacrificial region 113. Then, the exposed portion of the sacrificial region 113 is etched away. Specifically, a portion of the sacrificial region directly below the dummy gate structure is etched away, or all of the sacrificial region between the sidewalls and directly below the dummy gate structure is etched away, so as to form a cavity 200. The exposed portion of the sacrificial region 113 in this manner is located between the two sidewalls 500 so that the cavity 200 formed by etching away the exposed portion of the sacrificial region 113 is just located between the two sidewalls 500. The cavity 200 is filled with an insulating material to form the isolation region 300. Finally, step E is performed to form a gate structure 410 between the two sidewalls 500, as shown in FIG. 19. Moreover, when the sacrificial region is a sacrificial layer penetrating through the fin part, all of the sacrificial region in the fin part 110 may be etched away, with the cavity penetrating through the fin part.

The method according to the third embodiment has an advantage that the isolation region is self-aligned. For one skilled in the art, without the need for a special positioning and alignment step, the isolation region can be formed directly below the gate structure. This structure has an excellent short-channel effect and can effectively reduce the leakage current between the source region and the drain region below the gate structure. On the other hand, the method according to the third embodiment can also etch away the entire sacrificial region without the problem that the upper fin part collapses or is peeled off. Since the interlayer dielectric layer has been formed on the upper fin part before the sacrificial region is etched, the bonding force between the interlayer dielectric layer and the upper fin part can provide sufficient stability for the upper fin part. The upper fin part still remains in position even in a case that all of the sacrificial region or sacrificial layer below the upper fin part is etched away. When an isolation region is required to be formed below the entire upper fin part, one skilled person in the art can use a substrate having a sacrificial layer and apply the method according to the third embodiment.

### The Fourth Embodiment

Moreover, the disclosure also provides a fin-type semiconductor device structure as shown in FIG. 11. The device is provided with a fin-type substrate 100 including a lower substrate 180 and a fin part 110, a source region 6002 and drain region 6001 in the fin part 110, and a gate structure across the fin part 110 between the source region 6002 and the drain region 6001. In FIG. 11, the reference numeral 400 represents the dummy gate structure. The dummy gate structure 400 is replaced by the gate structure after the replacement gate process. A portion of the fin part below the gate structure is a channel region. A shallow trench isolation 105 is located at both sides of the fin part 110 in the y-direction and below the gate structure. A sidewall 500 is located at both side of the gate structure in the x-direction. An isolation region 300 is formed in the fin part 110 and between the channel region and the lower substrate. The fin-type semiconductor device structure further includes an interlayer dielectric which is located in the x-direction at both sides of the sidewall 500. The fin part 110 includes an upper fin part 114, a sacrificial layer 113 and a lower fin part 112. The fin part 110 has a top surface with a width preferably between 1 to 10 nm. It may have rectangular cross sections at both ends, as shown in FIG. 6, or triangular cross sections at both ends, as shown in FIG. 12. Its top surface may be a curved smooth surface. The fin part with triangular cross sections at both ends has better mechanical stability, and the fin part with rectangular cross sections at both ends provides better gate controllability in the resultant device.

Particularly, when the fin part 110 has rectangular cross sections at both ends, the upper fin part 114 may be a rectangular parallelepiped structure with rounded corners, or of a cylindrical shape. The upper fin part 114 is formed to have a substantially rectangular structure with rounded corner if the rounding degree is low. However, the upper fin part 114 is formed to have a substantially cylindrical structure if the rounding degree is high.

The height of the isolation region is preferably between 5 and 20 nm, and the material of the isolation region may be SiO2 and/or HfO2. The top surface of the shallow trench isolation 105 is lower than the top surface of the isolation region 300. When the top surface of the shallow trench isolation 105 is lower than the top surface of the isolation region 300, the gate structure may be made to cover more the upper fin part in the z-direction. This characteristic may reduce a leakage current, enhance a driving current, and enhance gate controllability.

The sacrificial region 113 is exposed at both sides of the fin part 110 in the y-direction. The isolation region 300 is formed in the sacrificial region 113. The sacrificial region 113 may be a sacrificial layer penetrating through the fin part 110, or one or more sacrificial segments.

The material of the lower fin part 112 may be Si, the material of the sacrificial region 113 is SiGe, and the material of the upper fin part 114 is Si. Alternatively, the material of the lower fin part 112 may be Si, the material of the sacrifice part 113 is SiGe, and the material of the upper fin part 114 is SiGe with Ge content 10% lower than that of the sacrificial region 113. Particularly, the material of the sacrificial region 113 may be SiGe with content of 40% Ge and the material of the upper fin part 114 is SiGe with content of 30% Ge. The structure with a SiGe upper fin part can be used to form PMOS devices. SiGe can improve the mobility of carrier holes in PMOS devices, improve the performance of the trench and enhance gate controllability.

Additionally, when the material of the upper fin part 114 is Si, the surface of the fin part 110 may have a SiGe epitaxial layer, and may have a Si epitaxial layer on the SiGe epitaxial layer. Alternatively, when the material of the upper fin part 114 is SiGe, the surface of the fin part 110 may have a Si epitaxial layer. If the thickness of the above Si epitaxial layer is less than 5 nm, it is more suitable for forming a PMOS semiconductor device. The Si epitaxial layer having a smaller thickness can provide compressive stress on the underlying SiGe epitaxial layer or the upper SiGe fin part, so as to improve the hole mobility of the SiGe and improve the channel performance of the PMOS device. If the Si epitaxial layer has a larger thickness, it is more suitable for forming an NMOS device, because the Si epitaxial layer has a better surface state, in which electrons are carriers of NMOS device.

Particularly, a plurality of isolation regions 300 may be present at different locations of a device in the x-direction. The isolation regions 300 can be substantially located below the source region 6002, and/or substantially located below the drain region, and/or substantially located below the gate structure. The number, locations, size of isolation regions 300 may be determined in accordance with the different performance requirements for forming the devices.

When the isolation region 300 is located only in the fin part 110 below the source region 6002 or the drain region 6001, the isolation region 300 has better isolation effect, and the side of the device structure without the isolation region 300 has better mechanical strength and thermal conductivity. Because the upper fin part 114 is connected with the lower fin part 112 through the sacrificial layer, the sacrificial layer 113 has better thermal conductivity than that of the isolation region 300, and it is coupled with the upper fin part 114 and the lower fin part 112 tightly, and mechanical strength is thus high. When the isolation region 300 is short in the x-direction, the device has better thermal conductivity and mechanical strength. When there are a plurality of isolation regions 300 in the sacrificial layer 113, the isolation effect of the device is better. When the gate has a length larger than 120 nm in the x-direction, one or more short isolation regions 300, which are shorter in the x-direction, are located in the sacrificial layer 113. This structure reduces the leakage current between the source and the drain regions and maintains better mechanical strength. The length of the short isolation region 300 in the x-direction should be less than four times the length of the fin part 110 in the y-direction.

Different locations of the isolation region in the device have different effects on the device performance, including the following aspects.

1. The isolation region 300 is only located below the drain region 6001. In the structure, the sacrificial layer 113 is still located in the fin part 110 below the source region 6002 and the gate structure, and connects the upper fin part 114 with the lower fin part 112. This structure appears to have better thermal conductivity and higher mechanical strength. Meanwhile, the leakage current of the drain region 6001 is reduced because the drain region 6001 is isolated from the lower substrate 180.

2. The isolation region 300 is only located below the drain region 6001 and a portion of the gate structure. This structure can reduce the parasitic capacitance between the gate structure and the lower fin part 112, while reducing the leakage current of the drain region 6001.

3. The isolation region 300 is located below the gate structure, and the length of the isolation region in the x-direction may be equal to the length of the gate structure in the x-direction. When the length of the gate structure in the x-direction is larger, the length of the isolation region in the x-direction is smaller than the length of the gate structure. This structure has an excellent short-channel effect and can effectively reduce the leakage current between the source region 6002 and the drain region 6001 below the gate structure.

4. For the device with a longer gate structure in the x-direction, there are a plurality of short isolation regions 300 in the fin part, which have a smaller length in the x-direction. This structure can improve the isolation effect, while ensuring the mechanical stability of the device and improving the yield.

In the fin-type semiconductor structure according to the third embodiment, the isolation region 300 is located directly below the gate structure 410. The length of the isolation region is equal to the length of the gate structure in the x-direction, or smaller than the length of the gate structure. This structure can effectively reduce the leakage current between the source region 6002 and the drain region 6001 below the gate structure 410. Specifically, the isolation region may also penetrate through the entire fin part.

Specifically, the material of the interlayer dielectric may be SiO2, having a height the same as the length of the gate structure 410.

Additionally, the isolation region 300 has an under-cut region 301 on both sides in the y-direction. The under-cut region 301 is recessed in the y-direction with respect to both sides of the fin part 110 by a distance less than one quarter of the width of the fin part 110 in the y-direction. The position where the under-cut region 301 contacts the lower fin part 112 has a smooth and curved surface as shown in FIG. 14. When the isolation region 300 is located below the gate structure, the gate structure may cover the surface of the under-cut region 301 and extend into the fin part in the y-direction, covering a portion of the surface of the lower end of the upper fin part 114, if the under-cut region 301 is provided. This structure can enhance the gate controllability and greatly improve the device performance.

Additionally, the present disclosure also provides an integrated chip in view of actual needs and production conditions. Such a chip is formed by integrating semiconductor devices. The semiconductor device integrated in the chip includes a fin-type semiconductor structure having an isolation region according to the embodiment, and a fin-type semiconductor structure without an isolation region. The fin-type semiconductor structure without an isolation region and the fin-type semiconductor structure with an isolation region according to the embodiment can be produced in the same production line, so that sacrificial regions may be provided therein. However, in view of performance requirements of a device, the isolation regions are not formed in some of the fin-type semiconductor structures, which is the fin-type semiconductor structures without an isolation.

Various embodiments of the present disclosure have been described above. The application of the present invention is not limited to the specific processes, structures, manufacturing approaches, materials, means, methods and step in the above description. On the basis of the above disclosure with respect to the present invention, one ordinary skilled person will understand that the existing or future processes, structures, manufacturing approaches, materials, means, methods and steps, if having the functions the same as or similar to those described in the embodiments of the present invention, can also be used according to the present invention. On the basis of the above disclosure with respect to the present invention, one ordinary skilled person will understand that the existing or future processes, structures, manufacturing approaches, materials, means, methods and steps, if having the functions the same as or similar to those described in the embodiments of the present invention, can also be used according to the present invention.

1. A fin-type semiconductor structure comprising:
a fin-type substrate provided with a lower substrate and a fin part;
a source region and a drain region formed in the fin part;
a gate structure formed across the fin part between the source region and the drain region, with a portion of the fin part below the gate structure being a channel region;
a shallow trench isolation formed at both sides of the fin part; and
one or more isolation regions formed in the fin part between the channel region and the lower substrate.

2. The fin-type semiconductor structure according to claim 1, wherein the fin part has rectangular cross sections at both ends, or the fin part has triangular cross sections at both ends.

3. The fin-type semiconductor structure according to claim 1, wherein a top surface of the fin part is a smooth and curved surface.

4. The fin-type semiconductor structure according to claim 1, wherein the fin-type semiconductor structure comprises interlayer dielectrics and sidewalls at both sides of the gate structure, and the interlayer dielectrics have the same height as that of the gate structure.

5. The fin-type semiconductor structure according to claim 1, wherein the isolation region is located below the source region and/or the drain region.

6. The fin-type semiconductor structure according to claim 1, wherein the isolation region is located below the gate structure, having a length equal to or smaller than that of the gate structure.

7. The fin-type semiconductor structure according to claim 1, wherein the fin-type semiconductor structure comprises a sacrificial region formed in the fin part, and the isolation region is formed in the sacrificial region which is exposed at both sides of the fin part.

8. The fin-type semiconductor structure according to claim 7, wherein the sacrificial region is a sacrificial layer penetrating through the fin part, or the sacrificial region comprises one or more sacrificial segments.

9. The fin-type semiconductor structure according to claim 1, wherein the fin part comprises an upper fin part, a sacrificial region and a lower fin part.

10. The fin-type semiconductor structure according to claim 9, wherein the upper fin part is made of Si and a SiGe epitaxial layer is formed on a surface of the fin part; or the upper fin part is made of SiGe and a Si epitaxial layer is formed on a surface of the fin part.

11. The fin-type semiconductor structure according to claim 10, wherein a Si epitaxial layer is formed on the SiGe epitaxial layer.

12. The fin-type semiconductor structure according to claim 1, wherein an under-cut region is formed at both sides of the isolation region, which is recessed with a distance with respect to both sides of the fin part less than one quarter of a width of the fin part.

13. A method for forming a fin-type semiconductor structure comprising:
step A, providing a substrate for forming a fin-type substrate having a lower substrate and a fin part having a sacrificial region;
step B, etching a portion of or all of the sacrificial region to form a cavity, forming an isolation region by filling the cavity with an insulating material, forming a shallow trench isolation continuously by the insulating material, exposing a top surface of the fin part by chemical mechanical planarization, and etching the shallow trench isolation to expose the fin part;
step C, forming a dummy gate structure across the fin part, forming sidewalls at both sides of the dummy gate structure, and forming a source region and a + of the dummy gate structure;
step D, forming a metal gate structure by a replacement gate process in which the dummy gate structure is replaced.

14. The method according to claim 13, wherein step A comprises:
providing the substrate having the sacrificial region which is a sacrificial layer penetrating through the fin part; or providing the substrate and forming a sacrificial region having one or more sacrificial segments by ion implantation;
forming an etching protection layer on the substrate, forming a mask on the etching protection layer, etching the etching protection layer to expose a portion of the substrate, etching a portion of the substrate to form a fin part having an upper fin part, a sacrificial layer and a lower fin part.

15. The fin-type semiconductor structure according to claim 13, wherein the step A comprises: forming the fin part by etching, the fin part having rectangular cross sections or triangular cross sections at both ends.

16. The fin-type semiconductor structure according to claim 13, wherein a cavity is formed by etching in the fin part below the drain region and/or source region.

17. The fin-type semiconductor structure according to claim 13, wherein a cavity is formed by etching a portion of or all of the sacrificial region below the gate structure.

18. The fin-type semiconductor structure according to claim 13, after step B, further comprising:
forming a SiGe epitaxial layer on the surface of the fin part and the cavity by epitaxial growth, or
forming a Si epitaxial layer on the surface of the fin part and the cavity by epitaxial growth.

19. The fin-type semiconductor structure according to claim 18, further comprising forming a Si epitaxial layer on the SiGe epitaxial layer by epitaxial growth.

20. The fin-type semiconductor structure according to claim 13, before the step C of forming the dummy gate structure, further comprising forming an under-cut region by etching back the isolation region, wherein the dummy gate structure formed at step C covers the surface of the under-cut region and extends into the fin part.
